(19) United States
(12) Patent Application Publication
(10) Pub. No.: US 2026/0341386 A1
(43) Pub. Date: Oct. 29, 2026

(54) SEMICONDUCTOR DEVICE AND TEST METHOD OF THE SAME

(71) Applicant: SK hynix Inc., Icheon-si (KR)

(72) Inventors: Jae Woo PARK, Icheon-si (KR); Tae Gun YOO, Icheon-si (KR); Seok Won LEE, Icheon-si (KR); Jung Ho LEE, Icheon-si (KR)

(21) Appl. No.: 19/355,792

(22) Filed: Oct. 10, 2025

(30) Foreign Application Priority Data
Apr. 29, 2025 (KR) 10-2025-0056188

(51) Int. Cl. G11C 29/12; G11C 29/14

(52) U.S. Cl. CPC G11C 29/1201; G11C 29/14; G11C 2029/1202

(57) ABSTRACT

An operating method of a semiconductor device includes entering a test mode, storing data in memory cells connected to three word lines that are consecutive to each other, repeating an active-precharge operation on each of the three word lines a preset number of times, reading the data of memory cells connected to a center word line, among the three word lines, and storing an address corresponding to the center word line as a fail address based on the results of the reading. Repeating the active-precharge operation includes activating two word lines other the center word line, among the three word lines, to a voltage level higher than the level of a normal word line driving voltage and activating the center word line to a voltage level lower than the level of the normal word line driving voltage.

### CROSS-REFERENCE TO RELATED APPLICATION

This application claims priority under 35 U.S.C. §119(a) to Korean Patent Application No. 10-2025-0056188, filed in the Korean Intellectual Property Office on Apr. 29, 2025, the entire contents of which are incorporated herein by reference.

### BACKGROUND

Embodiments relate to an integrated circuit technology and, more particularly, to a semiconductor device and a test method of the same.

### RELATED ART

As the semiconductor device is more highly integrated, it gradually becomes difficult to obtain a stable operating characteristic of a MOS transistor. In particular, DRAM includes a cell transistor that is connected to a memory cell composed of a capacitor and that connects the memory cell to a word line and a bit line. Characteristics of the cell transistor that need to be obtained, such as a threshold voltage, a current driving ability, and an operating speed, reach the ceiling because a gate line width is sharply reduced and the size of the cell transistor is also decreased due to a fine (i.e., higher resolution) process used to fabricate the cell transistor.

A fail memory cell including a cell transistor having a characteristics that has not been obtained needs to be detected through tests because the fail memory cell reduces the reliability of a semiconductor device.

### SUMMARY

In an embodiment, an operating method of a semiconductor device may include a test mode entry process of entering a test mode, a process of storing data in memory cells connected to three word lines that are consecutive to each other, a process of repeating an active-precharge operation on each of the three word lines that are consecutive to each other by a preset number, a process of reading data of memory cells connected to a center word line, among the three word lines that are consecutive to each other, and a process of storing an address corresponding to the center word line as a fail address based on the results of the reading. The process of repeating the active-precharge operation includes a process of activating two word lines except the center word line, among the three word lines that are consecutive to each other, to a voltage level higher than the level of a normal word line driving voltage and a process of activating the center word line to a voltage level lower than the level of the normal word line driving voltage.

In an embodiment, a semiconductor device may include a word line driver configured to drive a plurality of word lines to the level of a word line driving voltage, a sense amplifier array configured to detect and amplify data of memory cells through a plurality of bit lines, a memory cell array including a plurality of memory cells formed at locations at which the plurality of word lines and the plurality of bit lines intersect, and a test control circuit configured to store data in memory cells connected to each of three word lines that are consecutive to each other by controlling the word line driver and the sense amplifier array when the semiconductor device enters a test mode, configured to repeat an active-precharge operation on each of the three word lines that are consecutive to each other by a preset number, configured to read the data of memory cells connected to a center word line, among the three word lines that are consecutive to each other, and configured to store an address corresponding to the center word line as a fail address based on the results of the reading.

In an embodiment, an operating method of a semiconductor device may include a test mode entry process of entering a test mode, a process of storing data in memory cells connected to each of a first word line, a second word line, and a third word line that are consecutive to each other, a process of repeating an active-precharge operation on each of the first to third word lines by a preset number, a process of reading the data of the memory cells connected to the second word line, and a process of storing an address corresponding to the second word line as a fail address based on the results of the reading. The process of repeating the active-precharge operation on each of the first to third word lines may include a process of performing the active-precharge operation on the first word line, a process of performing the active-precharge operation on the third word line after the active-precharge operation for the first word line is completed, and a process of performing the active-precharge operation on the second word line after the active-precharge operation for the third word line is completed.

In an embodiment, an operating method of a semiconductor device may include a test mode entry process of entering a test mode, a process of storing data in memory cells connected to each of a first word line, a second word line, and a third word line that are consecutive to each other, a process of repeating an active-precharge operation on each of the first to third word lines by a preset number, a process of reading the data of the memory cells connected to the second word line, and a process of storing an address corresponding to the second word line as a fail address based on the results of the reading. The process of repeating the active-precharge operation on each of the first to third word lines may include a process of performing the active-precharge operation on the first word line, a process of performing the active-precharge operation on the third word line after the active-precharge operation for the first word line is completed, and a process of performing the active-precharge operation on the second word line after the active-precharge operation for the third word line is completed.

### BRIEF DESCRIPTION OF THE DRAWINGS

FIG. 1 illustrates a construction of a semiconductor device 100 according to an embodiment of the present disclosure.

FIGS. 2 to 5 are flowcharts for describing a test method of the semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a memory device capable of detecting a fail memory cell and a test method of the same.

It is possible to improve the reliability of a semiconductor device.

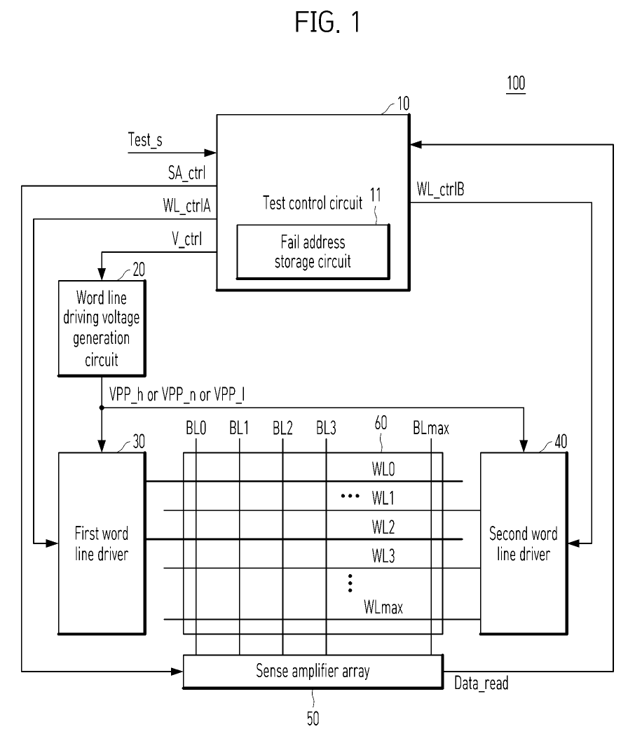

FIG. 1 illustrates a construction of a semiconductor device 100 according to an embodiment of the present disclosure.

The semiconductor device 100 according to an embodiment of the present disclosure may include a test control circuit 10, a word line driving voltage generation circuit 20, a first word line driver 30, a second word line driver 40, a sense amplifier array 50, and a memory cell array 60.

When receiving a test entry signal Test_s, the test control circuit 10 may generate a first word line control signal WL_ctrlA, a second word line control signal WL_ctrlB, a word line driving voltage level control signal V_ctrl, and a sense amplifier control signal SA_ctrl. The test control circuit 10 may control the word line driving voltage generation circuit 20 through the word line driving voltage level control signal V_ctrl. The test control circuit 10 may control the first word line driver 30 through the first word line control signal WL_ctrlA. The test control circuit 10 may control the second word line driver 40 through the second word line control signal WL_ctrlB. The test control circuit 10 may control the sense amplifier array 50 through the sense amplifier control signal SA_ctrl.

The test control circuit 10 may include a fail address storage circuit 110. The test control circuit 10 may receive read data Data_read from the sense amplifier array 50 and compare the read data Data_read and preset test data. In this case, when the read data Data_read is different from the preset test data, the test control circuit 10 may store the address of a memory cell from which the read data Data_read are output in the fail address storage circuit 11. In this case, the address stored in the fail address storage circuit 10 may include a row address that selects a word line.

The word line driving voltage generation circuit 20 may adjust the level of a word line driving voltage VPP based on the word line driving voltage level control signal V_ctrl. For example, the word line driving voltage generation circuit 20 may select one word line driving voltage, among a first word line driving voltage VPP_h, a second word line driving voltage VPP_n, and a third word line driving voltage VPP_l having different levels, based on the word line driving voltage level control signal V_ctrl, and may output the selected word line driving voltage. In this case, the level of the first word line driving voltage VPP_h may be the highest, and the level of the third word line driving voltage VPP_l may be the lowest. The second word line driving voltage VPP_n may be a voltage that activates a word line in a normal situation other than a case in which tests are performed. The selected word line driving voltage that is output from the word line driving voltage generation circuit 20 may be provided to the first word line driver 30 and the second word line driver 40.

The first word line driver 30 and the second word line driver 40 may select one word line, among a plurality of word lines WL0 to WLmax, based on the first word line control signal WL_ctrlA and the second word line control signal WL_ctrlB, respectively. Furthermore, the first word line driver 30 and the second word line driver 40 may drive the selected word line to the level of a voltage supplied by the word line driving voltage generation circuit 20. In this case, unselected word lines may be driven to a negative voltage level.

For example, the first word line driver 30 may control the driving of even-numbered word lines WL0, WL2, …, among the plurality of word lines WL0 to WLmax, based on the first word line control signal WL_ctrlA. More specifically, the first word line driver 30 may select one word line, among the even-numbered word lines WL0, WL2, …, based on the first word line control signal WL_ctrlA, and may drive the selected word line to the level of a voltage supplied by the word line driving voltage generation circuit 20. In this case, the first word line driver 30 may drive unselected even-numbered word lines to a negative voltage level.

Furthermore, the second word line driver 40 may control the driving of odd-numbered word lines WL1, WL3, …, among the plurality of word lines WL0 to WLmax, based on the second word line control signal WL_ctrlB. More specifically, the second word line driver 40 may select one word line, among the odd-numbered word lines WL1, WL3, …, based on the second word line control signal WL_ctrlB, and may drive the selected word line to the level of a voltage supplied by the word line driving voltage generation circuit 20. In this case, the second word line driver 40 may drive unselected odd-numbered word lines to a negative voltage level.

The sense amplifier array 50 may output data stored in a memory cell as the read data Data_read by detecting and amplifying the data through at least one selected bit line, among a plurality of bit lines BL0 to BLmax, based on the sense amplifier control signal SA_ctrl. Furthermore, the sense amplifier array 50 may change the levels of the plurality of bit lines BL0 to BLmax to a specific level based on the sense amplifier control signal SA_ctrl.

For example, the sense amplifier array 50 may include a plurality of sense amplifiers (not illustrated). The plurality of sense amplifiers may be electrically connected to the plurality of bit lines BL0 to BLmax, respectively. At least one sense amplifier, among the plurality of sense amplifiers, may be selected based on the sense amplifier control signal SA_ctrl. The selected at least one sense amplifier may detect and amplify data stored in a memory cell through a bit line that is electrically connected to the selected at least one sense amplifier. Furthermore, each of the plurality of sense amplifiers may change the level of a bit line connected to each sense amplifier into a specific level based on the sense amplifier control signal SA_ctrl.

The memory cell array 60 may include a plurality of memory cells (not illustrated). The plurality of memory cells may be respectively disposed locations at which the plurality of bit lines BL0 to BLmax and the plurality of word lines WL0 to WLmax intersect. For example, each of the plurality of memory cells may include a cell transistor and a capacitor. Each of the plurality of memory cells may be configured to electrically connect the capacitor and a respective bit line when a respective word line is driven.

Test methods of the semiconductor device constructed as above according to embodiments of the present disclosure are described as follows.

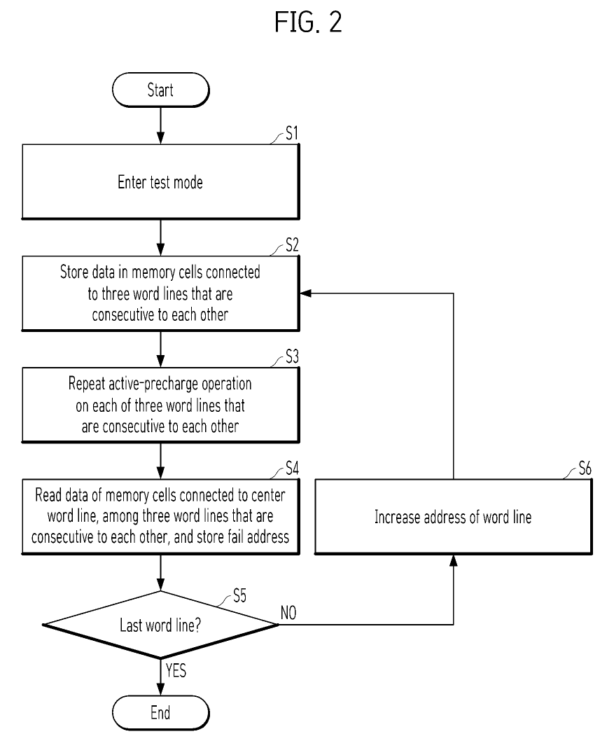

FIGS. 2 to 5 are flowcharts for describing a test method of the semiconductor device according to an embodiment of the present disclosure.

FIG. 2 is a flowchart for describing a test method of the semiconductor device according to an embodiment of the present disclosure.

Referring to FIG. 2, the test method of the semiconductor device according to an embodiment of the present disclosure may include a test mode entry process S1, a data storage process S2, an active-precharge repetition process S3, a read and fail address storage process S4, a last word line confirmation process S5, and a word line address increase process S6.

The test mode entry process S1 may include a process of receiving, by the test control circuit 10, the test entry signal Test_s. In response, the semiconductor device may enter a test mode.

The data storage process S2 may include a process of storing data in memory cells connected to three (n-1, n, and n+1 (n is a natural number)) word lines that are consecutive (and therefore physically adjacent) to each other. For example, low data may be stored in the memory cells connected to the (n-1)-th and (n+1)-th word lines, respectively, and high data may be stored in the memory cells connected to the n-th word line.

The active-precharge repetition process S3 may include a process of repeating an operation of activating and then precharging each of the three (n-1)-th, n-th, and (n+1)-th word lines that are consecutive to each other by a preset number. For example, the active-precharge repetition process S3 may include a process of driving each of the (n-1)-th word line and the (n+1)-th word line to the level of the first word line driving voltage VPP_h a preset number of times and driving the n-th word line to the level of the third word line driving voltage VPP_l a preset number of times.

The read and fail address storage process S4 may include a process of reading data from the memory cells connected to a center word line (i.e., the n-th word line), among the three (n-1)-th, n-th, and (n+1)-th word lines that are consecutive to each other, comparing the read data and the data stored in the memory cells connected to the n-th word line in the data storage process S2, and storing the address of the n-th word line as a fail address when the number of bits of the read data having different values than the corresponding bits in the data stored in the memory cells is a preset number or more.

The last word line confirmation process S5 may include a process of confirming whether the center word line (i.e., the n-th word line), among the three (n-1)-th, n-th, and (n+1)-th word lines that are consecutive to each other, is the last word line WLmax of the memory cell array 60.

When the n-th word line is the last word line WLmax of the memory cell array 60 (Yes) in the last word line confirmation process S5, the test method of the semiconductor device according to an embodiment of the present disclosure may be terminated.

When the n-th word line is not the last word line WLmax of the memory cell array 60 (No) in the last word line confirmation process S5, the word line address increase process S6 may be performed.

The word line address increase process S6 may include a process of increasing the address of a word line so that the data storage process S2 can be performed on three n-th, (n+1)-th, and (n+2)-th word lines that are subsequently consecutive to each other.

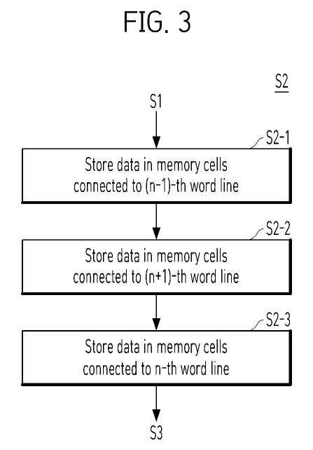

FIG. 3 is a diagram for more specifically describing the data storage process S2 of FIG. 2.

The data storage process S2 may include a first data storage process S2-1, a second data storage process S2-2, and a third data storage process S2-3.

The first data storage process S2-1 may include a process of storing low data in the memory cells connected to the (n-1)-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the (n-1)-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a low level by controlling the sense amplifier array 50 through the sense amplifier control signal SA_ctrl. In this case, the memory cells connected to the (n-1)-th word line may store low data.

The second data storage process S2-2 may include a process of storing low data in the memory cells connected to the (n+1)-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the (n+1)-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a low level by controlling the sense amplifier array 50 through the sense amplifier control signal SA_ctrl. In this case, the memory cells connected to the (n+1)-th word line may store low data.

The third data storage process S2-3 may include a process of storing low data in the memory cells connected to the n-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the n-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a high level by controlling the sense amplifier array 50 through the sense amplifier control signal SA_ctrl. In this case, the memory cells connected to the n-th word line may store high data.

As described above, when storing data in memory cells connected to the three (n-1)-th, n-th, and (n+1)-th word lines that are consecutive to each other, the data storage process S2 may include storing data in the memory cells connected to the (n-1)-th word line first and then storing data in the memory cells connected to the (n+1)-th word line. Furthermore, an operation of storing data in the memory cells connected to the n-th word line may be lastly performed in the data storage process S2. Furthermore, in the data storage process S2, the values of the data stored in the memory cells connected to the (n-1)-th word line and the memory cells connected to the (n+1)-th word line and the value of the data stored in the memory cells connected to the n-th word line may be different.

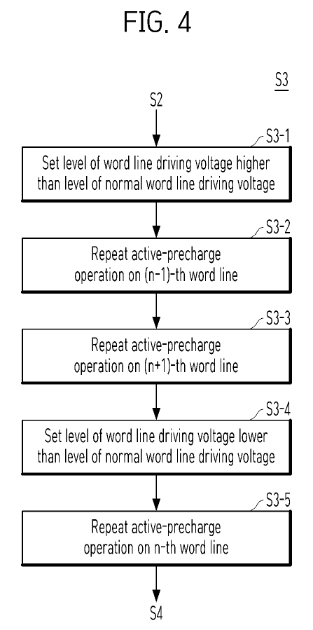

FIG. 4 is a diagram for more specifically describing the active-precharge repetition process S3 of FIG. 2.

Referring to FIG. 4, the active-precharge repetition process S3 may include a first word line driving voltage level setting process S3-1, a first active-precharge repetition process S3-2, a second active-precharge repetition process S3-3, a second word line driving voltage level setting process S3-4, and a third active-precharge repetition process S3-5.

The first word line driving voltage level setting process S3-1 may include a process of setting the level of the word line driving voltage. For example, the first word line driving voltage level setting process S3-1 may include a process of setting the level of the word line driving voltage to a level higher than the level of a normal word line driving voltage (e.g., higher than the second word line driving voltage VPP_n). More specifically, the first word line driving voltage level setting process S3-1 may include a process of selecting the first word line driving voltage VPP_h, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the first word line driving voltage VPP_h is selected from among the first, second, and third word line driving voltages VPP_h, VPP_n, and VPP_l and output.

The first active-precharge repetition process S3-2 may include a process of repeating an operation of activating and then precharging the (n-1)-th word line a preset number of times. In this case, the voltage level of the activated (n-1)-th word line may be the level of the first word line driving voltage VPP_h, and the voltage level of the precharged (n-1)-th word line may be a negative voltage level. That is, the first active-precharge repetition process S3-2 may include a process of driving the (n-1)-th word line to the level of the first word line driving voltage VPP_h a preset number of times. Referring to FIG. 1, the test control circuit 10 may repeat an operation of selecting the (n-1)-th word line, from among the plurality of word lines WL0 to WLmax, and driving the selected (n-1)-th word line to the level of the first word line driving voltage VPP_h and then driving the selected (n-1)-th word line to a negative voltage level a preset number of times by controlling the first word line driver 30 and the second word line driver 40 through the first word line control signal WL_ctrlA and the second word line control signal WL_ctrlB. In this case, the remaining word lines other than the (n-1)-th word line, among the plurality of word lines WL0 to WLmax, may be driven to a negative voltage level.

The second active-precharge repetition process S3-3 may include a process of repeating an operation of activating and then precharging the (n+1)-th word line a preset number of times. In this case, the voltage level of the activated (n+1)-th word line may be the level of the first word line driving voltage VPP_h, and the voltage level of the precharged (n+1)-th word line may be a negative voltage level. That is, the second active-precharge repetition process S3-3 may include a process of driving the (n+1)-th word line to the level of the first word line driving voltage VPP_h a preset number of times. Referring to FIG. 1, the test control circuit 10 may repeat an operation of selecting the (n+1)-th word line, from among the plurality of word lines WL0 to WLmax, and driving the selected (n+1)-th word line to the level of the first word line driving voltage VPP_h and then driving the selected (n+1)-th word line to a negative voltage level a preset number of times by controlling the first word line driver 30 and the second word line driver 40 through the first word line control signal WL_ctrlA and the second word line control signal WL_ctrlB. In this case, the remaining word lines other than the (n+1)-th word line, among the plurality of word lines WL0 to WLmax, may be driven to a negative voltage level.

The second word line driving voltage level setting process S3-4 may include a process of setting the level of the word line driving voltage. For example, the second word line driving voltage level setting process S3-4 may include a process of setting the level of the word line driving voltage to a level lower than a normal word line driving voltage (e.g., lower than the second word line driving voltage VPP_n). More specifically, the second word line driving voltage level setting process S3-4 may include a process of selecting the third word line driving voltage VPP_l, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the third word line driving voltage VPP_l is selected from among the first, second, and third word line driving voltages VPP_h, VPP_n, and VPP_l and output.

The third active-precharge repetition process S3-5 may include a process of repeating an operation of activating and then precharging the n-th word line a preset number of times. In this case, the voltage level of the activated n-th word line may be the level of the third word line driving voltage VPP_l, and the voltage level of the precharged n-th word line may be a negative voltage level. That is, the third active-precharge repetition process S3-5 may include a process of driving the n-th word line to the level of the third word line driving voltage VPP_l a preset number of times. Referring to FIG. 1, the test control circuit 10 may repeat an operation of selecting the n-th word line, among the plurality of word lines WL0 to WLmax, and driving the selected n-th word line to the level of the third word line driving voltage VPP_l and then driving the selected n-th word line to a negative voltage level a preset number of times by controlling the first word line driver 30 and the second word line driver 40 through the first word line control signal WL_ctrlA and the second word line control signal WL_ctrlB. In this case, the remaining word lines other than the n-th word line, among the plurality of word lines WL0 to WLmax, may be driven to a negative voltage level.

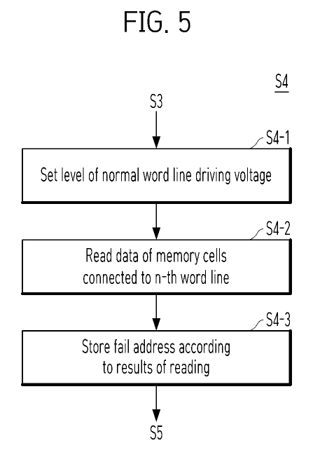

FIG. 5 is a diagram for more specifically describing the read and fail address storage process S4 of FIG. 2.

Referring to FIG. 5, the read and fail address storage process S4 may include a third word line driving voltage level setting process S4-1, a read process S4-2, and a fail address storage process S4-3.

The third word line driving voltage level setting process S4-1 may include a process of setting the level of the word line driving voltage. For example, the third word line driving voltage level setting process S4-1 may include a process of setting the level of the word line driving voltage to the level of a normal word line driving voltage (e.g., to the second word line driving voltage VPP_n). More specifically, the third word line driving voltage level setting process S4-1 may include a process of selecting the second word line driving voltage VPP_n, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the second word line driving voltage VPP_n, is selected from among the first, second, and third word line driving voltages VPP_h, VPP_n, and VPP_l and output.

The read process S4-2 may include a process of reading the data of the memory cells connected to the n-th word line. For example, the read process S4-2 may include a process of driving the n-th word line to the level of the second word line driving voltage VPP_n, a process of detecting and amplifying the data of the memory cells connected to the n-th word line driven through the plurality of bit lines BL0 to BLmax by activating the sense amplifier array 50, and a process of transmitting the detected and amplified data to the test control circuit 10. Referring to FIG. 1, the test control circuit 10 may control the first word line driver 30 and the second word line driver 40 through the first word line control signal WL_ctrlA and the second word line control signal WL_ctrlB so that the n-th word line, among the plurality of word lines WL0 to WLmax, is selected and the selected n-th word line is driven to the level of the second word line driving voltage VPP_n. The test control circuit 10 may control the sense amplifier array 50 through the sense amplifier control signal SA_ctrl so that the data of the memory cells connected to the n-th word line driven to the level of the second word line driving voltage VPP_n through the plurality of bit lines BL0 to BLmax are detected and amplified. The sense amplifier array 50 may provide the detected and amplified data, that is, the read data Data_read, to the test control circuit 10.

The fail address storage process S4-3 may include a process of comparing the data stored in the n-th word line in the data storage process S2 and the data read in the read process S4-2 and storing an address corresponding to the n-th word line as a fail address based on the results of the comparison. For example, the fail address storage process S4-3 may include a process of comparing the data (e.g., data having a high level) stored in the n-th word line in the data storage process S2 and the data read in the read process S4-2 and a process of storing an address (e.g., a row address) corresponding to the n-th word line as a fail address when the number of bits of data among the read data having values different from the value a corresponding bit of the stored data is greater than a preset number. For example, in the case where high data was stored, the fail address storage process S4-3 may include a process of storing an address corresponding to the n-th word line as a fail address when the number of bits of low data, among the read data, is greater than a preset number. Referring to FIG. 1, the test control circuit 10 may compare the read data Data_read provided by the sense amplifier array 50 and the data stored in the data storage process S2, and may store an address (e.g., a row address) corresponding to the n-th word line in the fail address storage circuit 11 as a fail address based on the results of the comparison. In this case, when the number of bits of data among the read data Data_read having values different from the value of the corresponding bit of the stored data, is greater than a preset number, the test control circuit 10 may store an address corresponding to the n-th word line as a fail address. Thus, in the provided example, when the number of bits of low data, among the read data Data_read, is greater than a preset number, the test control circuit 10 may store an address corresponding to the n-th word line as a fail address.

The semiconductor device constructed as above and the test method of the same according to embodiments of the present disclosure are described as follows assuming that n=1.

Referring to FIGS. 1 and 2, the test mode entry process S1 may be performed. For example, when the test control circuit 10 receives the test entry signal Test_s, the semiconductor device 100 may enter the test mode.

The data storage process S2 may be performed.

For example, the test control circuit 10 may store data in the memory cells connected to the 0-th word line WL0, the first word line WL1, and the second word line WL2 by controlling the first word line driver 30 and the second word line driver 40 through the first word line control signal WL_ctrlA and the second word line control signal WL_ctrlB and controlling the sense amplifier array 50 through the sense amplifier control signal SA_ctrl. In this case, low data may be stored in the memory cells connected to the 0-th word line WL0 and the second word line WL2, and high data may be stored in the memory cells connected to the first word line WL1. Furthermore, after the data are stored in the memory cells connected to the 0-th word line WL0, data may be stored in the memory cells connected to the second word line WL2. Finally, data may be stored in the memory cells connected to the first word line WL1.

The active-precharge repetition process S3 may be performed.

For example, the test control circuit 10 may provide the first word line driving voltage VPP_h to the first word line driver 30 and the second word line driver 40 by controlling the word line driving voltage generation circuit 20 through the word line driving voltage level control signal V_ctrl. The test control circuit 10 may repeat an operation of activating the 0-th word line WL0 to the level of the first word line driving voltage VPP_h and then precharging the 0-th word line WL0 to a negative voltage level a preset number of times by controlling the first word line driver 30 and the second word line driver 40 through the first word line control signal WL_ctrlA and the second word line control signal WL_ctrlB. Thereafter, the test control circuit 10 may repeat an operation of activating the second word line WL2 to the level of the first word line driving voltage VPP_h and then precharging the second word line WL2 to a negative voltage level a preset number of times by controlling the first word line driver 30 and the second word line driver 40 through the first word line control signal WL_ctrlA and the second word line control signal WL_ctrlB. When the repetition of the active-precharge operation of the second word line WL2 is completed, the test control circuit 10 may provide the third word line driving voltage VPP_l to the first and second word line drivers 30 by controlling the word line driving voltage generation circuit 20 through the word line driving voltage level control signal V_ctrl. The test control circuit 10 may repeat an operation of activating the first word line WL1 to the level of the third word line driving voltage VPP_l and then precharging the first word line WL1 to a negative voltage level a preset number of times by controlling the first word line driver 30 and the second word line driver 40 through the first word line control signal WL_ctrlA and the second word line control signal WL_ctrlB.

The read and fail address storage process S4 may be performed.

For example, the test control circuit 10 may provide the second word line driving voltage VPP_n to the first word line driver 30 and the second word line driver 40 by controlling the word line driving voltage generation circuit 20 through the word line driving voltage level control signal V_ctrl. The test control circuit 10 may drive the first word line WL1 to the level of the second word line driving voltage VPP_n by controlling the first word line driver 30 and the second word line driver 40 through the first word line control signal WL_ctrlA and the second word line control signal WL_ctrlB. The test control circuit 10 may detect and amplify the data of the memory cells connected to the first word line WL1 by controlling the sense amplifier array 50 through the sense amplifier control signal SA_ctrl. In this case, the sense amplifier array 50 may detect and amplify the data of the memory cells connected to the first word line WL1 through the plurality of bit lines BL0 to BLmax. When the number of bits of data among the read data Data_read having values different from the value of the corresponding bit of the data stored in the data storage process S2 is greater than a preset number, the test control circuit 10 may store a row address corresponding to the first word line in the fail address storage circuit 11 as a fail address.

The last word line confirmation process S5 may be performed.

For example, the test control circuit 10 may confirm whether the word line WL1 driven in the read and fail address storage process S4 is the last word line WLmax. The word line address increase process S6 may be performed because the word line WL1 driven in the read and fail address storage process S4, that is, the first word line WL1, is not the last word line WLmax.

The word line address increase process S6 may include a process of increasing the value of n by +1. For example, the test control circuit 10 may select the three word lines WL1, WL2, and WL3 that are consecutive to each other after performing the data storage process S2.

The data storage process S2, the active-precharge repetition process S3, and the read and fail address storage process S4 may be performed on each of the first word line, the second word line, and the third word line.

The data storage process S2, the active-precharge repetition process S3, and the read and fail address storage process S4 may be repeated until the word line driven in the read and fail address storage process S4 is the last word line WLmax.

The test operation of the semiconductor device according to an embodiment of the present disclosure may be terminated when the word line driven in the read and fail address storage process S4 is the last word line WLmax. In this case, the reason why data having a high level are stored in the memory cells connected to the n-th word line, low data are stored in the memory cells connected to the (n-1)-th word line and the (n+1)-th word line, and each of the (n-1)-th word line and the (n+1)-th word line is activated to the first word line driving voltage VPP_h having a higher level than the normal word line driving voltage VPP_n and then precharged is for applying stress to the memory cells connected to the n-th word line by shaking the level of the n-th word line by using a coupling phenomenon. Furthermore, the reason why the n-th word line is activated to the third word line driving voltage VPP_l having a lower level than the normal word line driving voltage VPP_n and then precharged is for changing the value of data stored in memory cells having a bad characteristic, among the memory cells connected to the n-th word line, into a high level.

As described above, the semiconductor device and the test method of the same according to embodiments of the present disclosure can detect memory cells having a relatively bad characteristic, among the memory cells included in the memory cell array 60, that is, fail memory cells, on the basis of the address of a word line.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

### DETAILED DESCRIPTION

FIG. 2 is a flowchart for describing a test method of the semiconductor device according to an embodiment of the present disclosure.

Referring to FIG. 2, the test method of the semiconductor device according to an embodiment of the present disclosure may include a test mode entry process S1, a data storage process S2, an active-precharge repetition process S3, a read and fail address storage process S4, a last word line confirmation process S5, and a word line address increase process S6.

The test mode entry process S1 may include a process of receiving, by the test control circuit 10, the test entry signal Test_s. In response, the semiconductor device may enter a test mode.

The data storage process S2 may include a process of storing data in memory cells connected to three (n-1, n, and n+1 (n is a natural number)) word lines that are consecutive (and therefore physically adjacent) to each other. For example, low data may be stored in the memory cells connected to the (n-1)-th and (n+1)-th word lines, respectively, and high data may be stored in the memory cells connected to the n-th word line.

The active-precharge repetition process S3 may include a process of repeating an operation of activating and then precharging each of the three (n-1)-th, n-th, and (n+1)-th word lines that are consecutive to each other by a preset number. For example, the active-precharge repetition process S3 may include a process of driving each of the (n-1)-th word line and the (n+1)-th word line to the level of the first word line driving voltage VPP_h a preset number of times and driving the n-th word line to the level of the third word line driving voltage VPP_l a preset number of times.

The read and fail address storage process S4 may include a process of reading data from the memory cells connected to a center word line (i.e., the n-th word line), among the three (n-1)-th, n-th, and (n+1)-th word lines that are consecutive to each other, comparing the read data and the data stored in the memory cells connected to the n-th word line in the data storage process S2, and storing the address of the n-th word line as a fail address when the number of bits of the read data having different values than the corresponding bits in the data stored in the memory cells is a preset number or more.

The last word line confirmation process S5 may include a process of confirming whether the center word line (i.e., the n-th word line), among the three (n-1)-th, n-th, and (n+1)-th word lines that are consecutive to each other, is the last word line WLmax of the memory cell array 60.

When the n-th word line is the last word line WLmax of the memory cell array 60 (Yes) in the last word line confirmation process S5, the test method of the semiconductor device according to an embodiment of the present disclosure may be terminated.

When the n-th word line is not the last word line WLmax of the memory cell array 60 (No) in the last word line confirmation process S5, the word line address increase process S6 may be performed.

The word line address increase process S6 may include a process of increasing the address of a word line so that the data storage process S2 can be performed on three n-th, (n+1)-th, and (n+2)-th word lines that are subsequently consecutive to each other.

FIG. 3 is a diagram for more specifically describing the data storage process S2 of FIG. 2.

The data storage process S2 may include a first data storage process S2-1, a second data storage process S2-2, and a third data storage process S2-3.

The first data storage process S2-1 may include a process of storing low data in the memory cells connected to the (n-1)-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the (n-1)-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a low level by controlling the sense amplifier array 50 through the sense amplifier control signal SA_ctrl. In this case, the memory cells connected to the (n-1)-th word line may store low data.

The second data storage process S2-2 may include a process of storing low data in the memory cells connected to the (n+1)-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the (n+1)-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a low level by controlling the sense amplifier array 50 through the sense amplifier control signal SA_ctrl. In this case, the memory cells connected to the (n+1)-th word line may store low data.

The third data storage process S2-3 may include a process of storing low data in the memory cells connected to the n-th word line. Referring to FIG. 1, the test control circuit 10 may control the word line driving voltage generation circuit 20 through the word line driving voltage level control signal V_ctrl so that the second word line driving voltage VPP_n is output from the word line driving voltage generation circuit 20. The test control circuit 10 may drive the n-th word line to the level of the second word line driving voltage VPP_n and drive the remaining word lines to a negative voltage level by controlling the first word line driver 30 and the second word line driver 40 through the first word line control signal WL_ctrlA and the second word line control signal WL_ctrlB, respectively. The test control circuit 10 may change the levels of the plurality of bit lines BL0 to BLmax into a high level by controlling the sense amplifier array 50 through the sense amplifier control signal SA_ctrl. In this case, the memory cells connected to the n-th word line may store high data.

As described above, when storing data in memory cells connected to the three (n-1)-th, n-th, and (n+1)-th word lines that are consecutive to each other, the data storage process S2 may include storing data in the memory cells connected to the (n-1)-th word line first and then storing data in the memory cells connected to the (n+1)-th word line. Furthermore, an operation of storing data in the memory cells connected to the n-th word line may be lastly performed in the data storage process S2. Furthermore, in the data storage process S2, the values of the data stored in the memory cells connected to the (n-1)-th word line and the memory cells connected to the (n+1)-th word line and the value of the data stored in the memory cells connected to the n-th word line may be different.

FIG. 4 is a diagram for more specifically describing the active-precharge repetition process S3 of FIG. 2.

Referring to FIG. 4, the active-precharge repetition process S3 may include a first word line driving voltage level setting process S3-1, a first active-precharge repetition process S3-2, a second active-precharge repetition process S3-3, a second word line driving voltage level setting process S3-4, and a third active-precharge repetition process S3-5.

The first word line driving voltage level setting process S3-1 may include a process of setting the level of the word line driving voltage. For example, the first word line driving voltage level setting process S3-1 may include a process of setting the level of the word line driving voltage to a level higher than the level of a normal word line driving voltage (e.g., higher than the second word line driving voltage VPP_n). More specifically, the first word line driving voltage level setting process S3-1 may include a process of selecting the first word line driving voltage VPP_h, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the first word line driving voltage VPP_h is selected from among the first, second, and third word line driving voltages VPP_h, VPP_n, and VPP_l and output.

The first active-precharge repetition process S3-2 may include a process of repeating an operation of activating and then precharging the (n-1)-th word line a preset number of times. In this case, the voltage level of the activated (n-1)-th word line may be the level of the first word line driving voltage VPP_h, and the voltage level of the precharged (n-1)-th word line may be a negative voltage level. That is, the first active-precharge repetition process S3-2 may include a process of driving the (n-1)-th word line to the level of the first word line driving voltage VPP_h a preset number of times. Referring to FIG. 1, the test control circuit 10 may repeat an operation of selecting the (n-1)-th word line, from among the plurality of word lines WL0 to WLmax, and driving the selected (n-1)-th word line to the level of the first word line driving voltage VPP_h and then driving the selected (n-1)-th word line to a negative voltage level a preset number of times by controlling the first word line driver 30 and the second word line driver 40 through the first word line control signal WL_ctrlA and the second word line control signal WL_ctrlB. In this case, the remaining word lines other than the (n-1)-th word line, among the plurality of word lines WL0 to WLmax, may be driven to a negative voltage level.

The second active-precharge repetition process S3-3 may include a process of repeating an operation of activating and then precharging the (n+1)-th word line a preset number of times. In this case, the voltage level of the activated (n+1)-th word line may be the level of the first word line driving voltage VPP_h, and the voltage level of the precharged (n+1)-th word line may be a negative voltage level. That is, the second active-precharge repetition process S3-3 may include a process of driving the (n+1)-th word line to the level of the first word line driving voltage VPP_h a preset number of times. Referring to FIG. 1, the test control circuit 10 may repeat an operation of selecting the (n+1)-th word line, from among the plurality of word lines WL0 to WLmax, and driving the selected (n+1)-th word line to the level of the first word line driving voltage VPP_h and then driving the selected (n+1)-th word line to a negative voltage level a preset number of times by controlling the first word line driver 30 and the second word line driver 40 through the first word line control signal WL_ctrlA and the second word line control signal WL_ctrlB. In this case, the remaining word lines other than the (n+1)-th word line, among the plurality of word lines WL0 to WLmax, may be driven to a negative voltage level.

The second word line driving voltage level setting process S3-4 may include a process of setting the level of the word line driving voltage. For example, the second word line driving voltage level setting process S3-4 may include a process of setting the level of the word line driving voltage to a level lower than a normal word line driving voltage (e.g., lower than the second word line driving voltage VPP_n). More specifically, the second word line driving voltage level setting process S3-4 may include a process of selecting the third word line driving voltage VPP_l, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the third word line driving voltage VPP_l is selected from among the first, second, and third word line driving voltages VPP_h, VPP_n, and VPP_l and output.

The third active-precharge repetition process S3-5 may include a process of repeating an operation of activating and then precharging the n-th word line a preset number of times. In this case, the voltage level of the activated n-th word line may be the level of the third word line driving voltage VPP_l, and the voltage level of the precharged n-th word line may be a negative voltage level. That is, the third active-precharge repetition process S3-5 may include a process of driving the n-th word line to the level of the third word line driving voltage VPP_l a preset number of times. Referring to FIG. 1, the test control circuit 10 may repeat an operation of selecting the n-th word line, among the plurality of word lines WL0 to WLmax, and driving the selected n-th word line to the level of the third word line driving voltage VPP_l and then driving the selected n-th word line to a negative voltage level a preset number of times by controlling the first word line driver 30 and the second word line driver 40 through the first word line control signal WL_ctrlA and the second word line control signal WL_ctrlB. In this case, the remaining word lines other than the n-th word line, among the plurality of word lines WL0 to WLmax, may be driven to a negative voltage level.

FIG. 5 is a diagram for more specifically describing the read and fail address storage process S4 of FIG. 2.

Referring to FIG. 5, the read and fail address storage process S4 may include a third word line driving voltage level setting process S4-1, a read process S4-2, and a fail address storage process S4-3.

The third word line driving voltage level setting process S4-1 may include a process of setting the level of the word line driving voltage. For example, the third word line driving voltage level setting process S4-1 may include a process of setting the level of the word line driving voltage to the level of a normal word line driving voltage (e.g., to the second word line driving voltage VPP_n). More specifically, the third word line driving voltage level setting process S4-1 may include a process of selecting the second word line driving voltage VPP_n, from among the first, second, and third word line driving voltages VPP_h, VPP_n, and VPP_l. Referring to FIG. 1, the test control circuit 10 may control the word line driving voltage generation circuit 20 through the word line driving voltage level control signal V_ctrl so that the second word line driving voltage VPP_n, is selected from among the first, second, and third word line driving voltages VPP_h, VPP_n, and VPP_l and output.

The read process S4-2 may include a process of reading the data of the memory cells connected to the n-th word line. For example, the read process S4-2 may include a process of driving the n-th word line to the level of the second word line driving voltage VPP_n, a process of detecting and amplifying the data of the memory cells connected to the n-th word line driven through the plurality of bit lines BL0 to BLmax by activating the sense amplifier array 50, and a process of transmitting the detected and amplified data to the test control circuit 10. Referring to FIG. 1, the test control circuit 10 may control the first word line driver 30 and the second word line driver 40 through the first word line control signal WL_ctrlA and the second word line control signal WL_ctrlB so that the n-th word line, among the plurality of word lines WL0 to WLmax, is selected and the selected n-th word line is driven to the level of the second word line driving voltage VPP_n. The test control circuit 10 may control the sense amplifier array 50 through the sense amplifier control signal SA_ctrl so that the data of the memory cells connected to the n-th word line driven to the level of the second word line driving voltage VPP_n through the plurality of bit lines BL0 to BLmax are detected and amplified. The sense amplifier array 50 may provide the detected and amplified data, that is, the read data Data_read, to the test control circuit 10.

The fail address storage process S4-3 may include a process of comparing the data stored in the n-th word line in the data storage process S2 and the data read in the read process S4-2 and storing an address corresponding to the n-th word line as a fail address based on the results of the comparison. For example, the fail address storage process S4-3 may include a process of comparing the data (e.g., data having a high level) stored in the n-th word line in the data storage process S2 and the data read in the read process S4-2 and a process of storing an address (e.g., a row address) corresponding to the n-th word line as a fail address when the number of bits of data among the read data having values different from the value a corresponding bit of the stored data is greater than a preset number. For example, in the case where high data was stored, the fail address storage process S4-3 may include a process of storing an address corresponding to the n-th word line as a fail address when the number of bits of low data, among the read data, is greater than a preset number. Referring to FIG. 1, the test control circuit 10 may compare the read data Data_read provided by the sense amplifier array 50 and the data stored in the data storage process S2, and may store an address (e.g., a row address) corresponding to the n-th word line in the fail address storage circuit 11 as a fail address based on the results of the comparison. In this case, when the number of bits of data among the read data Data_read having values different from the value of the corresponding bit of the stored data, is greater than a preset number, the test control circuit 10 may store an address corresponding to the n-th word line as a fail address. Thus, in the provided example, when the number of bits of low data, among the read data Data_read, is greater than a preset number, the test control circuit 10 may store an address corresponding to the n-th word line as a fail address.

The semiconductor device constructed as above and the test method of the same according to embodiments of the present disclosure are described as follows assuming that n=1.

Referring to FIGS. 1 and 2, the test mode entry process S1 may be performed. For example, when the test control circuit 10 receives the test entry signal Test_s, the semiconductor device 100 may enter the test mode.

The data storage process S2 may be performed.

For example, the test control circuit 10 may store data in the memory cells connected to the 0-th word line WL0, the first word line WL1, and the second word line WL2 by controlling the first word line driver 30 and the second word line driver 40 through the first word line control signal WL_ctrlA and the second word line control signal WL_ctrlB and controlling the sense amplifier array 50 through the sense amplifier control signal SA_ctrl. In this case, low data may be stored in the memory cells connected to the 0-th word line WL0 and the second word line WL2, and high data may be stored in the memory cells connected to the first word line WL1. Furthermore, after the data are stored in the memory cells connected to the 0-th word line WL0, data may be stored in the memory cells connected to the second word line WL2. Finally, data may be stored in the memory cells connected to the first word line WL1.

The active-precharge repetition process S3 may be performed.

For example, the test control circuit 10 may provide the first word line driving voltage VPP_h to the first word line driver 30 and the second word line driver 40 by controlling the word line driving voltage generation circuit 20 through the word line driving voltage level control signal V_ctrl. The test control circuit 10 may repeat an operation of activating the 0-th word line WL0 to the level of the first word line driving voltage VPP_h and then precharging the 0-th word line WL0 to a negative voltage level a preset number of times by controlling the first word line driver 30 and the second word line driver 40 through the first word line control signal WL_ctrlA and the second word line control signal WL_ctrlB. Thereafter, the test control circuit 10 may repeat an operation of activating the second word line WL2 to the level of the first word line driving voltage VPP_h and then precharging the second word line WL2 to a negative voltage level a preset number of times by controlling the first word line driver 30 and the second word line driver 40 through the first word line control signal WL_ctrlA and the second word line control signal WL_ctrlB. When the repetition of the active-precharge operation of the second word line WL2 is completed, the test control circuit 10 may provide the third word line driving voltage VPP_l to the first and second word line drivers 30 by controlling the word line driving voltage generation circuit 20 through the word line driving voltage level control signal V_ctrl. The test control circuit 10 may repeat an operation of activating the first word line WL1 to the level of the third word line driving voltage VPP_l and then precharging the first word line WL1 to a negative voltage level a preset number of times by controlling the first word line driver 30 and the second word line driver 40 through the first word line control signal WL_ctrlA and the second word line control signal WL_ctrlB.

The read and fail address storage process S4 may be performed.

For example, the test control circuit 10 may provide the second word line driving voltage VPP_n to the first word line driver 30 and the second word line driver 40 by controlling the word line driving voltage generation circuit 20 through the word line driving voltage level control signal V_ctrl. The test control circuit 10 may drive the first word line WL1 to the level of the second word line driving voltage VPP_n by controlling the first word line driver 30 and the second word line driver 40 through the first word line control signal WL_ctrlA and the second word line control signal WL_ctrlB. The test control circuit 10 may detect and amplify the data of the memory cells connected to the first word line WL1 by controlling the sense amplifier array 50 through the sense amplifier control signal SA_ctrl. In this case, the sense amplifier array 50 may detect and amplify the data of the memory cells connected to the first word line WL1 through the plurality of bit lines BL0 to BLmax. When the number of bits of data among the read data Data_read having values different from the value of the corresponding bit of the data stored in the data storage process S2 is greater than a preset number, the test control circuit 10 may store a row address corresponding to the first word line in the fail address storage circuit 11 as a fail address.

The last word line confirmation process S5 may be performed.

For example, the test control circuit 10 may confirm whether the word line WL1 driven in the read and fail address storage process S4 is the last word line WLmax. The word line address increase process S6 may be performed because the word line WL1 driven in the read and fail address storage process S4, that is, the first word line WL1, is not the last word line WLmax.

The word line address increase process S6 may include a process of increasing the value of n by +1. For example, the test control circuit 10 may select the three word lines WL1, WL2, and WL3 that are consecutive to each other after performing the data storage process S2.

The data storage process S2, the active-precharge repetition process S3, and the read and fail address storage process S4 may be performed on each of the first word line, the second word line, and the third word line.

The data storage process S2, the active-precharge repetition process S3, and the read and fail address storage process S4 may be repeated until the word line driven in the read and fail address storage process S4 is the last word line WLmax.

The test operation of the semiconductor device according to an embodiment of the present disclosure may be terminated when the word line driven in the read and fail address storage process S4 is the last word line WLmax. In this case, the reason why data having a high level are stored in the memory cells connected to the n-th word line, low data are stored in the memory cells connected to the (n-1)-th word line and the (n+1)-th word line, and each of the (n-1)-th word line and the (n+1)-th word line is activated to the first word line driving voltage VPP_h having a higher level than the normal word line driving voltage VPP_n and then precharged is for applying stress to the memory cells connected to the n-th word line by shaking the level of the n-th word line by using a coupling phenomenon. Furthermore, the reason why the n-th word line is activated to the third word line driving voltage VPP_l having a lower level than the normal word line driving voltage VPP_n and then precharged is for changing the value of data stored in memory cells having a bad characteristic, among the memory cells connected to the n-th word line, into a high level.

As described above, the semiconductor device and the test method of the same according to embodiments of the present disclosure can detect memory cells having a relatively bad characteristic, among the memory cells included in the memory cell array 60, that is, fail memory cells, on the basis of the address of a word line.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. An operating method of a semiconductor device, comprising:
a test mode entry process of entering a test mode;
when in the test mode:
a process of storing data in memory cells connected to three word lines that are consecutive to each other;
a process of repeating an active-precharge operation on each of the three word lines that are consecutive to each other by a preset number;
a process of reading data of memory cells connected to a center word line, among the three word lines that are consecutive to each other; and
a process of storing an address corresponding to the center word line as a fail address based on results of the reading,
wherein the process of repeating the active-precharge operation comprises:
a process of activating two word lines other than the center word line, among the three word lines that are consecutive to each other, to a voltage level higher than a level of a normal word line driving voltage, and
a process of activating the center word line to a voltage level lower than the level of the normal word line driving voltage.

2. The operating method of claim 1, wherein in the process of storing the data, the data stored in the memory cells connected to the center word line and data stored in memory cells connected to two word lines except the center word line have different data values.

3. The operating method of claim 2, wherein:
the three word lines that are consecutive to each other comprise a first word line, a second word line, and a third word line,
the second word line is the center word line, and
the process of storing the data comprises:
a process of storing data having a first level in memory cells connected to the first word line,
a process of storing data having the first level in memory cells connected to the third word line, and
a process of storing data having a second level different from the first level in memory cells connected to the second word line.

4. The operating method of claim 3, wherein:
the first level is a low level, and
the second level is a high level.

5. The operating method of claim 3, wherein the process of repeating the active-precharge operation comprises:
a process of repeating an operation of activating the first word line to a level of a voltage higher than the normal word line driving voltage and then precharging the first word line a preset number of times for the first word line,
a process of repeating an operation of activating the third word line to the level of the voltage higher than the normal word line driving voltage and then precharging the third word line a preset number of times for the second word line, and
a process of repeating an operation of activating the second word line to the level of the voltage lower than the normal word line driving voltage and then precharging the second word line a preset number of times for the third word line.

6. The operating method of claim 3, wherein the process of storing the address corresponding to the center word line as the fail address comprises:
a process of reading the data of the memory cells connected to the second word line,
a process of comparing the read data and the data stored in the memory cells connected to the second word line in the process of storing the data, and
a process of determining that a number of bits of data among the read data having values different from a value of corresponding bits of the stored data is greater than a preset number and storing an address corresponding to the second word line as the fail address.

7. A semiconductor device comprising:
a word line driver configured to drive a plurality of word lines to a level of a word line driving voltage;
a sense amplifier array configured to detect and amplify data of memory cells through a plurality of bit lines;
a memory cell array comprising a plurality of memory cells formed at locations at which the plurality of word lines and the plurality of bit lines intersect; and
a test control circuit configured to:
store data in memory cells connected to each of three word lines that are consecutive to each other by controlling the word line driver and the sense amplifier array when the semiconductor device enters a test mode,
repeat an active-precharge operation on each of the three word lines that are consecutive to each other a preset number of times ,
read data of memory cells connected to a center word line, among the three word lines that are consecutive to each other, and
store an address corresponding to the center word line as a fail address based on results of the reading.

8. The semiconductor device of claim 7, wherein when performing the active-precharge operation, the test control circuit controls a voltage level of the center word line activated, among the three word lines that are consecutive to each other, to be lower than a voltage level of each of remaining two word lines that are activated.

9. The semiconductor device of claim 7, wherein when performing the active-precharge operation, the test control circuit controls the active-precharge operation for the center word line to be performed later than the active-precharge operation for each of the remaining two word lines.

10. The semiconductor device of claim 7, wherein in the operation of storing the data in the memory cells connected to each of the three word lines that are consecutive to each other, the test control circuit controls the data stored in the memory cells connected to the center word line and data stored in memory cells connected to remaining two word lines, among the three word lines that are consecutive to each other, to have different levels.

11. The semiconductor device of claim 10, wherein the test control circuit is configured to cause data having a first level to be stored in the memory cells connected to the remaining two word lines and to cause data having a second level to be stored in the memory cells connected to the center word line.

12. The semiconductor device of claim 11, wherein in the operation of storing the address corresponding to the center word line as the fail address based on the results of the reading, the test control circuit determines that a number of bits of data having the first level, among the data read from the memory cells connected to the center word line, is greater than a preset number and in response stores the address corresponding to the center word line as the fail address.

13. An operating method of a semiconductor device, comprising:
a test mode entry process of entering a test mode;
a process of storing data in memory cells connected to each of a first word line, a second word line, and a third word line that are consecutive to each other;
a process of repeating an active-precharge operation on each of the first to third word lines by a preset number;
a process of reading the data of the memory cells connected to the second word line; and
a process of storing an address corresponding to the second word line as a fail address based on results of the reading,
wherein the process of repeating the active-precharge operation on each of the first to third word lines comprises:
a process of performing the active-precharge operation on the first word line,
a process of performing the active-precharge operation on the third word line after the active-precharge operation for the first word line is completed, and
a process of performing the active-precharge operation on the second word line after the active-precharge operation for the third word line is completed.

14. The operating method of claim 13, wherein in the process of storing the data, the data stored in the memory cells connected to the second word line and the data stored in the memory cells connected to each of the first and third word lines have different data values.

15. The operating method of claim 14, wherein the process of storing the data comprises:
a process of storing the data having a first level in the memory cells connected to the first word line,
a process of storing the data having the first level in the memory cells connected to the third word line, and
a process of storing the data having a second level different from the first level in the memory cells connected to the second word line.

16. The operating method of claim 13, wherein a voltage level of each of the first and third word lines that are activated in the process of performing the active-precharge operation on the first word line and the process of performing the active-precharge operation on the third word line is higher than a voltage level of the second word line that is activated in the process of performing the active-precharge operation on the second word line.

17. The operating method of claim 15, wherein the process of storing the address corresponding to the second word line as the fail address comprises:
a process of reading the data of the memory cells connected to the second word line, and
a process of determining that a number of bits of the data having the first level, among the read data, is greater than a preset number and in response storing the address corresponding to the second word line as the fail address.
